(19) United States
(12) Patent Application Publication
(10) Pub. No.: US 2026/0040844 A1
(43) Pub. Date: Feb. 5, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventor: Yoshitomo HASHIMOTO, Toyama-shi (JP)

(73) Assignee: Kokusai Electric Corporation, Tokyo (JP)

(21) Appl. No.: 19/286,722

(22) Filed: Jul. 31, 2025

(30) Foreign Application Priority Data
Aug. 1, 2024 (JP) 2024-126424

(51) Int. Cl. H01L 21/02; H01L 21/311; H10B 43/00

(52) U.S. Cl. CPC H01L 21/02312; H01L 21/0228; H01L 21/31116; H10B 43/00

(57) ABSTRACT

There is provided a technique that includes: (a) supplying a film-forming agent to the substrate having a recess on a surface thereof, the recess having a bottom surface formed by a first base and a side surface formed by a second base, and forming a first film on the first base with a thickness greater than a thickness of a first film formed on the second base; and (b) supplying an etching agent to the substrate, and removing the first film formed on the second base while leaving at least a part of the first film formed on the first base.

### CROSS-REFERENCE TO RELATED APPLICATION

This application is based upon and claims the benefit of priority from Japanese Patent Application No. 2024-126424, filed on Aug. 1, 2024, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor device, a process of forming a film on the surface of a substrate is often performed.

### SUMMARY

Some embodiments of the present disclosure provide a technique capable of precisely forming a film within a recess on a surface of a substrate.

According to one embodiment of the present disclosure, there is provided a technique that includes: (a) supplying a film-forming agent to a substrate having a recess on a surface thereof, the recess having a bottom surface formed by a first base and a side surface formed by a second base, and forming a first film on the first base with a thickness greater than a thickness of a first film formed on the second base; and (b) supplying an etching agent to the substrate, and removing the first film formed on the second base while leaving at least a part of the first film formed on the first base.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in one embodiment of the present disclosure, in which the portion of the process furnace 202 is illustrated in a vertical sectional view.

FIG. 2 is a schematic configuration diagram of the vertical process furnace of the substrate processing apparatus suitably used in one embodiment of the present disclosure, in which the portion of the process furnace 202 is illustrated in a sectional view taken along line A-A in FIG. 1.

FIG. 3 is a schematic configuration diagram of a controller 121 of the substrate processing apparatus suitably used in one embodiment of the present disclosure, in which a control system of the controller 121 is illustrated in a block diagram.

FIG. 4A is a partial cross-sectional enlarged view showing a surface portion of a substrate in one embodiment of the present disclosure having a recess on the surface thereof.

FIG. 4B is a partial cross-sectional enlarged view showing the surface portion of the substrate in one embodiment of the present disclosure after performing step A1 from the state shown in FIG. 4A. FIG. 4C is a partial cross-sectional enlarged view showing the surface portion of the substrate in one embodiment of the present disclosure after performing a cycle including steps A2 and A3 a predetermined number of times from the state shown in FIG. 4B. FIG. 4D is a partial cross-sectional enlarged view showing the surface portion of the substrate in one embodiment of the present disclosure after performing a cycle including steps B1 and B2 a predetermined number of times from the state shown in FIG. 4C. FIG. 4E is a partial cross-sectional enlarged view showing the surface portion of the substrate in one embodiment of the present disclosure after performing step C1 from the state shown in FIG. 4D. FIG. 4F is a partial cross-sectional enlarged view showing the surface portion of the substrate in one embodiment of the present disclosure after performing a cycle including steps C2 and C3 a predetermined number of times from the state shown in FIG. 4E.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of the Present Disclosure

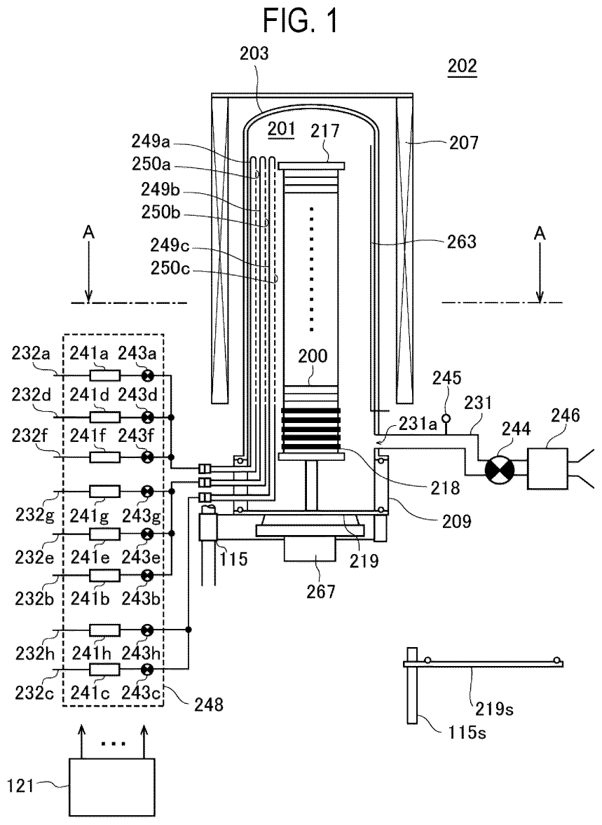

Hereinafter, one embodiment of the present disclosure will be described mainly with reference to FIGS. 1 to 3 and FIGS. 4A to 4F. The drawings used in the following description are all schematic, and the dimensional relationship of each element, the ratio of each element, and the like shown in the drawings do not necessarily match the actual ones. Moreover, the dimensional relationship of each element, the ratio of each element, and the like do not necessarily match between a plurality of drawings.

### (1) Configuration of Substrate Processing Apparatus

As shown in FIG. 1, a process furnace 202 of a substrate processing apparatus includes a reaction tube 203. A manifold 209 is disposed below the reaction tube 203. A process container is mainly composed of the reaction tube 203 and the manifold 209. A process chamber 201 is formed inside the process container. The process chamber 201 is configured to be capable of accommodating wafers 200 as substrates.

A heater 207 for heating the wafers 200 in the process chamber 201 is provided outside the reaction tube 203. The heater 207 also functions as an activation mechanism for thermally activating a gas in the process chamber 201. A temperature sensor 263 is provided inside the reaction tube 203.

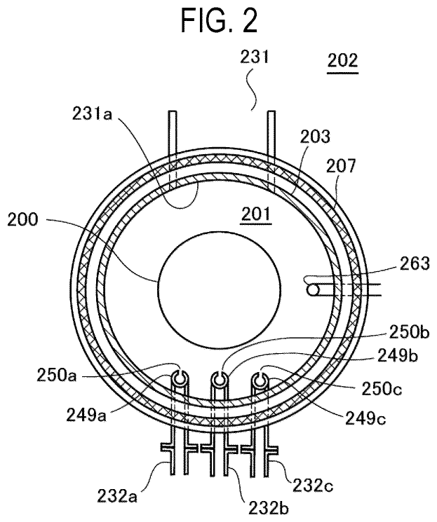

Nozzles 249a to 249c are provided in the process chamber 201. As shown in FIG. 2, the nozzles 249a to 249c are provided so as to extend upward in the arrangement direction of the wafers 200 along the inner wall of the reaction tube 203. A plurality of gas supply holes 250a to 250c are provided on the side surfaces of the nozzles 249a to 249c from the bottom to the top of the reaction tube 203.

Gas supply pipes 232a to 232c are connected to the nozzles 249a to 249c. Mass flow controllers (MFCs) 241a to 241c and valves 243a to 243c are provided on the gas supply pipes 232a to 232c. Gas supply pipes 232d and 232f are connected to the gas supply pipe 232a on the downstream side of the valve 243a. Gas supply pipes 232e and 232g are connected to the gas supply pipe 232b on the downstream side of the valve 243b. A gas supply pipe 232h is connected to the gas supply pipe 232c on the downstream side of the valve 243c. MFCs 241d to 241h and valves 241d to 241h are installed on the gas supply pipes 232d to 232h.

A modifying agent (first and second modifying agents) is supplied from the gas supply pipe 232a into the process chamber 201 via the MFC 241a, the valve 243a, and the nozzle 249a.

A film-forming agent (first and second film-forming agents) is supplied from the gas supply pipe 232b into the process chamber 201 via the MFC 241b, the valve 243b, and the nozzle 249b.

A reactant (first to fifth reactants) is supplied from the gas supply pipe 232c into the process chamber 201 via the MFC 241c, the valve 243c, and the nozzle 249c.

An etching agent is supplied from the gas supply pipe 232d into the process chamber 201 via the MFC 241d, the valve 243d, the gas supply pipe 232a, and the nozzle 249a.

A catalyst is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c. The inert gas acts as a purge gas, a carrier gas, a dilution gas, or the like.

A modifying agent supply system is mainly composed of the gas supply pipe 232a, the MFC 241a, and the valve 243a. A film-forming agent supply system is mainly composed of the gas supply pipe 232b, the MFC 241b, and the valve 243b. A reactant supply system is mainly composed of the gas supply pipe 232c, the MFC 241c, and the valve 243c. An etching agent supply system is mainly composed of the gas supply pipe 232d, the MFC 241d, and the valve 243d. A catalyst supply system is mainly composed of the gas supply pipe 232e, the MFC 241e, and the valve 243e. An inert gas supply system is mainly composed of the gas supply pipes 232f to 232h, the MFCs 241f to 241h, and the valves 243f to 243h. Any or all of the various supply systems described above may be configured as an integrated supply system 248 in which the valves 243a to 243h, the MFCs 241a to 241h, and the like are integrated.

An exhaust port 231a is provided below the reaction tube 203. A vacuum pump 246 is connected to the exhaust pipe 231 via a pressure sensor 245 and an APC (Auto Pressure Controller) valve 244. An exhaust system is mainly composed of the exhaust pipe 231, the APC valve 244, and the pressure sensor 245. The vacuum pump 246 may be included in the exhaust system.

A seal cap 219 is installed below the manifold 209. A rotation mechanism 267 for rotating a boat 217 (described later) is provided in the seal cap 219. The seal cap 219 is raised and lowered by a boat elevator 115. The boat elevator 115 functions as a transfer mechanism for transferring the wafers 200 into and out of the process chamber 201.

A shutter 219s capable of air-tightly closing the lower end opening of the manifold 209 is provided below the manifold 209. The opening/closing operation of the shutter 219s is controlled by a shutter opening/closing mechanism 115s.

The boat 217 as a substrate support tool is configured to support a plurality of wafers 200, for example 25 to 200 wafers 200, in multiple stages in a horizontal posture in a state in which the wafers 200 are aligned vertically with their centers aligned with each other. At the bottom of the boat 217, heat insulating plates 218 are supported in multiple stages.

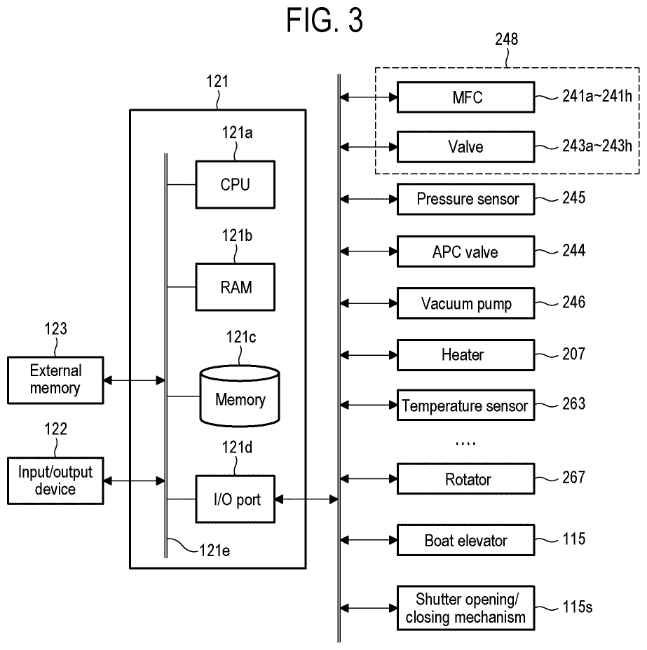

As shown in FIG. 3, the controller 121, which is a control unit, is configured as a computer that includes a CPU 121a, a RAM 121b, a memory device 121c, and an I/O port 121d. The RAM 121b, the memory device 121c, and the I/O port 121d are configured to be able to exchange data with the CPU 121a via an internal bus 121e. An input/output device 122 configured as a touch panel or the like is connected to the controller 121. An external memory device 123 can be connected to the controller 121.

The memory device 121c is composed of a flash memory, an HDD, an SSD, or the like. In the memory device 121c, there are readably recorded and stored a control program for controlling the operation of the processing apparatus, a process recipe in which procedures and conditions of substrate processing to be described later are written, and the like. The process recipe is a combination that causes the controller 121 to have the processing apparatus execute the respective procedures in a below-described substrate processing process so as to obtain a predetermined result. The process recipe functions as a program. Hereinafter, the process recipe, the control program and the like are collectively and simply referred to as a program (program product). Furthermore, the process recipe is also simply referred to as a recipe. When the term “program” is used herein, it may mean a case of including only the recipe, a case of including only the control program, or a case of including both the recipe and the control program.

The I/O port 121d is connected to the MFCs 241a to 241h, the valves 243a to 243h, the pressure sensor 245, the APC valve 244, the vacuum pump 246, the temperature sensor 263, the heater 207, the rotation mechanism 267, the boat elevator 115, the shutter opening/closing mechanism 115s, and the like. The I/O port 121d may further be connected to the etching unit.

The CPU 121a is configured to read and execute the control program from the memory device 121c and to read the recipe from the memory device 121c in response to an input of an operation command from the input/output device 122 or the like. The CPU 121a is configured to, according to the contents of the recipe thus read, control the flow rate adjustment operation for various substances by the MFCs 241a to 241h, the opening/closing operations of the valves 243a to 243h, the opening/closing operation of the APC valve 244, the pressure regulation operation by the APC valve 244 based on the pressure sensor 245, the start and stop of the vacuum pump 246, the temperature adjustment operation of the heater 207 based on the temperature sensor 263, the rotation and the rotation speed adjustment operation of the boat 217 by the rotation mechanism 267, the raising and lowering operation of the boat 217 by the boat elevator 115, the opening/closing operation of the shutter 219s by the shutter opening/closing mechanism 115s, and the like. The CPU 121a may be further configured to be capable of controlling the etching unit.

The controller 121 can be configured by installing the above-mentioned program recorded and stored in the external memory device 123 into a computer. The external memory device 123 includes a magnetic disk such as an HDD, an optical disk such as a CD, a semiconductor memory such as a USB memory or an SSD, and the like. The memory device 121c and the external memory device 123 are configured as computer-readable recording media. Hereinafter, these are collectively and simply referred to as a recording medium. When the term recording medium is used herein, it may include only the memory device 121c, only the external memory device 123, or both. The program may be provided to the computer using a communication means such as the Internet or the like.

### (2) Substrate Processing Process

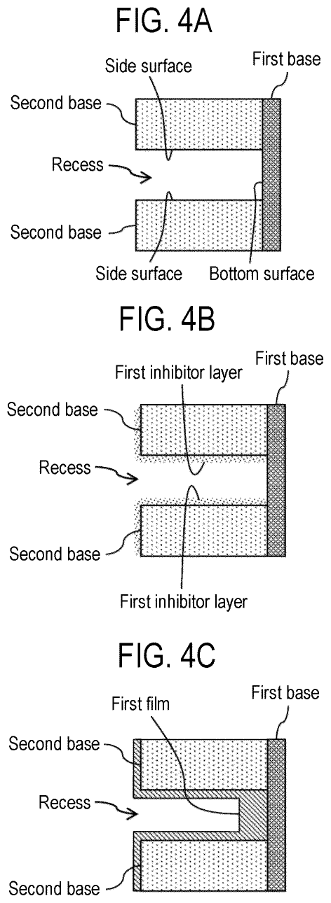

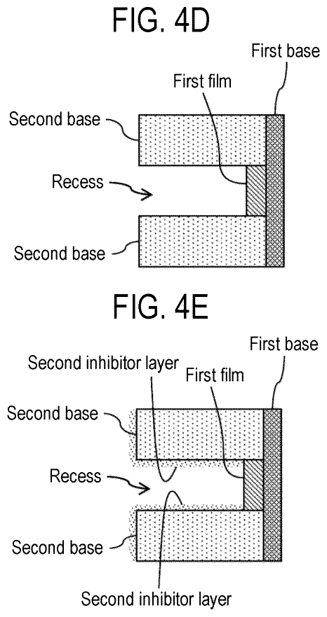

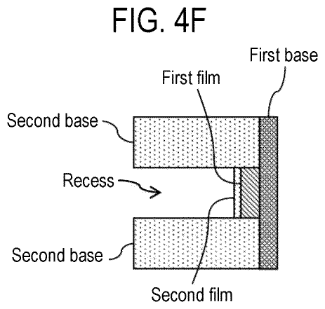

An example of a processing sequence for forming a film in a recess provided the surface of a wafer 200 as a substrate, as one process (method) of manufacturing a semiconductor device using the above-described substrate processing apparatus, will be described mainly with reference to FIGS. 4A to 4F. The series of processing sequences shown below are performed by the above-described substrate processing apparatus. In this case, the operation of each part constituting the substrate processing apparatus is controlled by the controller 121.

In the processing sequence according to the present embodiment, the following steps are performed: (a) step A of supplying a first film-forming agent to a wafer 200 having a recess on a surface thereof, the recess having a bottom surface formed by a first base and a side surface formed by a second base, and selectively forming a first film on the first base with a thickness greater than a thickness of a first film formed on the second base; and (b) step B of supplying an etching agent to the wafer 200, and removing the first film formed on the second base while leaving at least a part of the first film formed on the first base. FIG. 4A shows the state (initial state) inside the recess of the surface of the wafer 200 to be processed.

In the following example, there will be described a case where in step A, before supplying the first film-forming agent to the wafer 200, (a1) step A1 of supplying a first modifying agent to the wafer 200 to modify the surface of the second base selectively to the surface of the first base into a surface having a first termination that suppresses adsorption of at least a part of the first film-forming agent is performed. FIG. 4B shows the state inside the recess after performing step A1 from the state shown in FIG. 4A.

Furthermore, in the following example, there will be described a case where in step A, after performing step A1, a cycle including (a2) step A2 of supplying a first film-forming agent to the wafer 200 and (a3) step A3 of supplying a first reactant to the wafer 200 is performed a predetermined number of times (n_{A} times where n_{A} is an integer equal to or greater than 1). FIG. 4C shows the state inside the recess after performing the cycle including steps A2 and A3 a predetermined number of times from the state shown in FIG. 4B.

Furthermore, in the following example, there will be described a case where in step B, a cycle including (b1) step B1 of supplying a second reactant that reacts with the first film to the wafer 200 and (b2) step B2 of supplying an etching agent, which is a substance different from the second reactant, to the wafer 200 is performed a predetermined number of times (n_{B} times where n_{B} is an integer equal to or greater than 1). FIG. 4D shows the state inside the recess after performing the cycle including steps B1 and B2 a predetermined number of times from the state shown in FIG. 4C.

Furthermore, in the following example, there will be described a case where after performing step B, (c) step C of supplying a second film-forming agent to the wafer 200 to form a second film having a different composition from the first film on the first film.

Furthermore, in the following example, there will be described a case where in step C, before supplying the second film-forming agent to the wafer 200, (c1) step C1 of supplying a second modifying agent to the wafer 200 to modify the surface of the second base selectively to the surface of the first base into a surface having a second termination that suppresses adsorption of at least a part of the second film-forming agent is performed. FIG. 4E shows the state inside the recess after performing step C1 from the state shown in FIG. 4D.

Furthermore, in the following example, there will be described a case where in step C, after performing step C1, a cycle including (c2) step C2 of supplying a second film-forming agent to the wafer 200 and (c3) step C3 of supplying a third reactant to the wafer 200 is performed a predetermined number of times (n_{C} times where n_{C} is an integer equal to or greater than 1). FIG. 4F shows the state inside the recess after performing the cycle including step C2 and step C3 a predetermined number of times from the state shown in FIG. 4E.

In the present disclosure, the above-mentioned processing sequence may be denoted as follows.
Step A: first modifying agent→(first film-forming agent→first reactant)×n_{A}
Step B: (second reactant→etching agent)×n_{B}
Step C: second modifying agent→(second film-forming agent→third reactant)×n_{C}

The term “wafer” used herein may refer to a wafer itself or a stacked body of a wafer and a predetermined layer or film formed on the surface of the wafer. The phrase “a surface of a wafer” used herein may refer to a surface of a wafer itself or a surface of a predetermined layer or the like formed on a wafer. The expression “a predetermined layer is formed on a wafer” used herein may mean that a predetermined layer is directly formed on a surface of a wafer itself or that a predetermined layer is formed on a layer or the like formed on a wafer. The term “substrate” used herein may be synonymous with the term “wafer.”

As used herein, terms such as “agent,” and “substance” include at least one of gaseous substances and liquid substances. Liquid substances include mist-like substances. That is, each of the modifying agent, the film-forming agent, the reactant, the etching agent, and the catalyst described below may include a gaseous substance, a liquid substance such as a mist-like substance, or both.

The processing sequence according to the present embodiment will now be described in detail.

### (Wafer Charging and Boat Loading)

When a plurality of wafers 200 are charged to the boat 217 (wafer charging), the shutter 219s is moved by the shutter opening/closing mechanism 115s to open the lower end opening of the manifold 209 (shutter opening). Then, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b.

The wafer 200 to be processed has a three-dimensional structure such as a trench or a hole, i.e., a recess, on its surface. As shown in FIG. 4A, the recess has a bottom surface formed by a first base and a side surface formed by a second base. Such a structure can be formed by a known method, for example, by forming a layered structure of a second base, a sacrificial film and a second base on the surface of the wafer 200, patterning the layered structure, forming a first base on the side surface of the layered structure, and then selectively etching only the sacrificial film by an etching solution having a predetermined etching selectivity while suppressing etching of the first base and the second base.

The first base may be composed of a material containing a non-metal element, particularly a metalloid element (Si, B, Ge, As, Sb, Te, etc.) and nitrogen (N), such as silicon nitride (SiN), silicon carbonitride (SiCN), silicon boronitride (SiBN), silicon boron carbonitride (SiBCN), or the like.

The second base may be composed of a material containing a non-metal element, particularly a metalloid element and oxygen (O), such as silicon oxide (SiO), silicon oxynitride (SiON), silicon oxycarbide (SiOC), silicon oxycarbonitride (SiOCN), silicon boron oxynitride (SiBON), silicon boron carbon oxynitride (SiBCON), or the like.

The second base may be composed of a material containing a metal element (A1, Ti, Zr, Hf, Ta, Mo, etc.), a non-metal element (particularly, a metalloid element), and O, such as aluminum silicon oxide (AlSiO), titanium silicon oxide (TiSiO), zirconium silicon oxide (ZrSiO), hafnium silicon oxide (HfSiO), tantalum silicon oxide (TaSiO), molybdenum silicon oxide (MoSiO), or the like.

The second base may be composed of a material containing a metal element and O, such as aluminum oxide (AlO), titanium oxide (TiO), zirconium oxide (ZrO), hafnium oxide (HfO), tantalum oxide (TaO), molybdenum oxide (MoO), zirconium aluminum oxide (ZrAlO), hafnium aluminum oxide (HfAlO), or the like.

### (Pressure Regulation and Temperature Adjustment)

After the boat loading is completed, the inside of the process chamber 201, i.e., the space in which the wafer 200 exists, is evacuated into a vacuum (evacuated into a reduced pressure) by the vacuum pump 246 so that the pressure inside the process chamber 201 becomes a desired pressure (vacuum level). At this time, the pressure inside the process chamber 201 is measured by the pressure sensor 245, and the APC valve 244 is feedback-controlled based on the measured pressure information. In addition, the wafer 200 in the process chamber 201 is heated by the heater 207 so as to have a desired processing temperature. At this time, the power supply to the heater 207 is feedback-controlled based on the temperature information detected by the temperature sensor 263 so that the process chamber 201 has a desired temperature distribution. In addition, the rotation mechanism 267 starts rotating the wafer 200. The evacuation inside the process chamber 201 and the heating and rotation of the wafer 200 are all continued at least until the processing of the wafer 200 is completed.

### (Step A)

Subsequently, the following steps A1 to A3 are performed on the wafer 200 prepared in the process chamber 201.

### [Step A1]

In this step, the valve 243a is opened to allow a modifying agent (first modifying agent) to flow into the gas supply pipe 232a. The flow rate of the first modifying agent is adjusted by the MFC 241a. The first modifying agent is supplied into the process chamber 201 through the nozzle 249a, and is exhausted from the exhaust port 231a. At this time, the first modifying agent is supplied to the wafer 200 from the lateral side of the wafer 200, and the wafer 200 is exposed to the first modifying agent (first modifying agent supply and exposure). At this time, the valves 243f to 243h may be opened to supply an inert gas into the process chamber 201 through each of the nozzles 249a to 249c.

By performing this step under the processing conditions described later, as shown in FIG. 4B, it is possible to allow at least a part of the molecular structure of a molecule constituting the first modifying agent to be adsorbed onto the surface of the second base selectively to the surface of the first base, thereby forming a predetermined adsorption layer (first inhibitor layer). By using a below-described substance as the first modifying agent and forming a first inhibitor layer on the surface of the second base, the surface of the second base is modified into a surface terminated with a hydrocarbon group such as an alkyl group, hydrogen (H), or fluorine (F) selectively to the surface of the first base. These terminations (hydrocarbon group terminations, H terminations, or F terminations) function as an inhibitor that suppresses adsorption of a first film-forming agent to the surface of the second base in step A2 described later. That is, by performing this step, the surface of the second base is modified into a surface having a first termination that suppresses adsorption of at least a part of the first film-forming agent selectively to the surface of the first base.

In the present disclosure, the phrase “the surface of the second base is modified selectively to the surface of the first base” does not mean “only the surface of the second base is modified”, but means “among the surfaces of the first base and the second base, the surface of the second base is preferentially modified”. In other words, the term “selectively” indicates the relative magnitude of the degree of modification of the surface of the second base to the degree of modification of the surface of the first base, and does not completely exclude modification of the surface of the first base. The term “selectively” is used in substantially the same sense in each of the following steps.

After the surface of the second base is selectively modified, the valve 243a is closed to stop the supply of the first modifying agent to the wafer 200. Then, the process chamber 201 is evacuated to remove gaseous substances remaining in the process chamber 201 from the inside of the process chamber 201. Furthermore, the valves 243f to 243h are opened to supply an inert gas into the process chamber 201 to purge the inside of the process chamber 201 (purging).

Processing conditions when supplying the first modifying agent in step A1 are exemplified as follows.
Processing temperature: room temperature (25 degrees C.) to 500 degrees C., preferably room temperature to 250 degrees C.
Processing pressure: 1 to 2000 Pa, preferably 1 to 1000 Pa
Processing time: 1 second to 120 minutes, preferably 30 seconds to 60 minutes
First modifying agent supply flow rate: 0.001 to 3 slm, preferably 0.001 to 0.5 slm
Inert gas supply flow rate (per gas supply pipe): 0 to 20 slm

In this specification, the expression of a numerical range such as “25 to 500 degrees C.” means that the lower limit and the upper limit are included in the range. Therefore, for example, “25 to 500 degrees C.” means “25 degrees C. or more and 500 degrees C. or less”. The same applies to other numerical ranges. In this specification, the processing temperature means the temperature of the wafer 200 or the temperature in the process chamber 201, and the processing pressure means the pressure in the process chamber 201. In addition, the processing time means the time for which the processing continues. In addition, when the supply flow rate includes 0 slm, 0 slm means a case in which a substance is not supplied. These also hold true in the following description.

The first modifying agent may be, for example, a substance (aminosilane, or the like) in which hydrogen (H) and an amino group are bonded to Si, such as tris(dimethylamino)silane (Si[N(CH₃)₂]₃H), bis(diethylamino)silane (Si[N(C₂H₅)₂]₂H₂), bis(tertiary butylamino)silane (SiH₂[NH(C₄H₉)]₂), (diisobutylamino)silane (SiH₃[N(C₄H₉)₂]), or (diisopropylamino)silane (SiH₃[N(C₃H₇)₂]).

Furthermore, the first modifying agent may be, for example, a substance (alkylaminosilane, or the like) in which an amino group and a hydrocarbon group are bonded to Si, such as (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), or (dipropylamino)trimethylsilane ((C₃H₇)₂NSi(CH₃)₃).

The first modifying agent may be, for example, a halogen-containing substance such as fluorine (F), chlorine (Cl), bromine (Br), iodine (I), or the like. The halogen-containing substance used as the first modifying agent may be, for example, a fluorine (F)-containing substance such as fluorine (F2), nitrogen trifluoride (NF₃), chlorine trifluoride (ClF₃), chlorine fluoride (ClF), hydrogen fluoride (HF), or the like.

As the first modifying agent, one or more of these substances may be used.

The inert gas may be, for example, a nitrogen (N₂) gas, or a rare gas such as an argon (Ar) gas, a helium (He) gas, a neon (Ne) gas or a xenon (Xe) gas. As the inert gas, one or more of these gases may be used. This also applies to each step described later.

### [Step A2]

In this step, the valve 243b is opened to allow a film-forming agent (first film-forming agent) to flow into the gas supply pipe 232b. The flow rate of the first film-forming agent is adjusted by the MFC 241b. The film-forming agent is supplied into the process chamber 201 through the nozzle 249b, and is exhausted from the exhaust port 231a. At this time, the first film-forming agent is supplied to the wafer 200 from the lateral side of the wafer 200, and the wafer 200 is exposed to the first film-forming agent (first film-forming agent supply and exposure). At this time, the valves 243f to 243h may be opened to supply an inert gas into the process chamber 201 through each of the nozzles 249a to 249c.

By performing this step under the processing conditions described below, at least a part of the molecular structure of the molecule constituting the first film-forming agent is adsorbed onto the surfaces of the first and second bases, and an adsorption layer (first layer) of the first film-forming agent can be formed on these surfaces. As described above, by performing step A1, the surface of the second base is modified into a surface on which a first termination is formed (a surface having a film-forming inhibition effect). As a result, the amount of the first film-forming agent adsorbed onto the first base per unit area and unit time is greater than the amount of the first film-forming agent adsorbed onto the second base per unit area and unit time. That is, the thickness of the first layer formed on the first base is greater than the thickness of the first layer formed on the second base.

After the first layer is formed on the first base at a thickness greater than the thickness of the first layer formed on the second base, the valve 243a is closed to stop the supply of the first film-forming agent to the wafer 200. Then, by the above-described procedure, gaseous substances remaining in the process chamber 201 are removed from the inside of the process chamber 201, and the process chamber 201 is purged with the inert gas (purging).

Processing conditions when supplying the first film-forming agent in step A2 are exemplified as follows.
Processing temperature: room temperature (25 degrees C.) to 500 degrees C., preferably 350 to 400 degrees C.
Processing pressure: 1 to 2000 Pa, preferably 1 to 1333 Pa
Processing time: 1 to 180 seconds, preferably 10 to 120 seconds
First film-forming agent supply flow rate: 0.001 to 2 slm, preferably 0.01 to 1 slm
Inert gas supply flow rate (per gas supply pipe): 0 to 20 slm

The first film-forming agent may be, for example, a substance (e.g., an organic metal or a metal halide) containing a metal element as a first predetermined element, such as aluminum (Al), titanium (Ti), hafnium (Hf), zirconium (Zr), or the like. The first film-forming agent may be, for example, aluminum trichloride (AlCl₃), trimethylaluminum (Al(CH₃)₃), titanium tetrachloride (TiCl₄), hafnium tetrafluoride (HfCl₄), tetrakisethylmethylaminohafnium (Hf[N(CH₃)(CH₂CH₃)]₄), zirconium tetrafluoride (ZrCl₄), tetrakisethylmethylaminozirconium (Zr[N(CH₃)Cp]₄), or the like.

### [Step A3]

In this step, the valve 243c is opened to allow a reactant (first reactant) to flow into the gas supply pipe 232c. The flow rate of the first reactant is adjusted by the MFC 241c. The first reactant is supplied into the process chamber 201 through the nozzle 249c, and is exhausted from the exhaust port 231a. At this time, the first reactant is supplied to the wafer 200 from the lateral side of the wafer 200, and the wafer 200 is exposed to the first reactant (first reactant supply and exposure). At this time, the valves 243f to 243h may be opened to supply an inert gas into the process chamber 201.

By performing this step under the processing conditions described below, the first layer formed on each surface of the first base and the second base can be changed. For example, when an oxidizing agent is used as the first reactant, at least a part of the first layer can be oxidized to form an oxide layer (first oxide layer) containing the constituent elements of the first film-forming agent on each surface of the first base and the second base. In addition, for example, when a nitriding agent is used as the first reactant, at least a part of the first layer can be nitrided to form a nitride layer (first nitride layer) containing the constituent elements of the first film-forming agent on each surface of the first base and the second base.

After the first layers formed on the surfaces of the first and second bases are respectively changed, the valve 243c is closed to stop the supply of the reactant to the wafer 200. Then, by the above-mentioned procedure, gaseous substances remaining in the process chamber 201 are removed from the inside of the process chamber 201, and the process chamber 201 is purged with the inert gas.

Processing conditions when supplying the first reactant in step A3 are exemplified as follows.
Processing pressure: 1 to 4000 Pa, preferably 1 to 1333 Pa
First reactant supply flow rate: 0.01 to 20 slm, preferably 0.01 to 10 slm
   Other processing conditions may be the same as the processing conditions when the supplying the first film-forming agent in step A2.

The first reactant may be an oxidizing agent. The oxidizing agent may be, for example, oxygen (O₂), ozone (O₃), water vapor (H₂O), nitrous oxide (N₂O), nitric oxide (NO), nitrogen dioxide (NO₂), carbon dioxide (CO₂), or carbon monoxide (CO). One or more of these oxygen (O)-containing substances may be used as the first reactant.

The first reactant may be a nitriding agent. The nitriding agent may be, for example, hydrogen nitride such as ammonia (NH₃), diazene (N₂H₂), hydrazine (N₂H₄), or N₃H₈. One or more of these nitrogen (N)-containing substances may be used as the first reactant.

### [Performing a Predetermined Number of Times]

Then, a cycle including steps A2 and A3 is performed a predetermined number of times (n_{A} times where n_{A} is an integer of 1 or 2 or more). As a result, as shown in FIG. 4C, a first film can be formed on each surface of the first base and the second base. As described above, in step A2, the thickness of the first layer formed on the first base is greater than the thickness of the first layer formed on the second base. Therefore, by performing the cycle including steps A2 and A3 a predetermined number of times, the thickness of the first film formed on the first base becomes greater than the thickness of the first film formed on the second base.

When a substance containing the above-mentioned metal element is used as the first film-forming agent, a film containing the above-mentioned metal element can be formed as the first film.

Furthermore, when a substance containing the above-mentioned metal element is used as the first film-forming agent and the above-mentioned oxidizing agent is used as the first reactant, a film containing the above-mentioned metal element and O (i.e., a metal oxide film) can be formed as the first film. In this embodiment, as a more preferred example of the first film, an oxide dielectric film (oxide high-k film) having a larger electron trap density than a SiN film, such as an aluminum oxide film (AlO film), a titanium oxide film (TiO film), a hafnium oxide film (HfO film), or a zirconium oxide film (ZrO film), can be formed.

Furthermore, when a substance containing the above-mentioned metal element is used as the first film-forming agent and the above-mentioned nitriding agent is used as the first reactant, a film containing the above-mentioned metal element and N (i.e., a metal nitride film) can be formed as the first film. In this embodiment, as a more preferred example of the first film, a nitride dielectric film (nitride high-k film) having a larger electron trap density than a SiN film, such as an aluminum nitride film (AlN film), a titanium nitride film (TiN film), a hafnium nitride film (HfN film), or a zirconium nitride film (ZrN film), can be formed.

### (Step B)

Subsequently, the following steps B1 and B2 are performed.

### [Step B1]

In this step, the valve 243c is opened to allow a reactant (second reactant) to flow into the gas supply pipe 232c. The flow rate of the second reactant is adjusted by the MFC 241c. The second reactant is supplied into the process chamber 201 through the nozzle 249c, and is exhausted from the exhaust port 231a. At this time, the second reactant is supplied to the wafer 200 from the lateral side of the wafer 200, and the wafer 200 is exposed to the second reactant (second reactant supply and exposure). At this time, the valves 243f to 243h may be opened to supply an inert gas into the process chamber 201.

By performing this step under the processing conditions described below, the surface of the first film formed inside the recess in step A can be caused to react with the second reactant, and an altered layer having a predetermined composition and a predetermined thickness can be formed on the surface of the first film. For example, when the first film is a film (AlO film) mainly composed of aluminum oxide (A1₂O₃), the first film can be caused to react with the second reactant by supplying a boron (B)- and halogen element-containing substance as the second reactant to this film, and a part of the surface of the first film can be modified (converted) into an altered layer of a predetermined thickness containing aluminum halide (e.g., AlCl₃, or the like). This reaction can be allowed to proceed uniformly over almost the entire surface of the first film, and the composition and thickness of the altered layer can be made approximately uniform over the entire surface of the first film.

After the altered layer is formed on the surface of the first film by the reaction with the second reactant, the valve 243d is closed to stop the supply of the second reactant to the wafer 200. Then, the process chamber 201 is evacuated to remove gaseous substances remaining in the process chamber 201 from the inside of the process chamber 201. Furthermore, the valves 243f to 243h are opened to supply an inert gas into the process chamber 201 to purge the inside of the process chamber 201 (purging).

Processing conditions when supplying the second reactant in step B1 are exemplified as follows.
Processing temperature: 200 to 900 degrees C., preferably 300 to 800 degrees C.
Processing pressure: 150 to 400 Pa, preferably 200 to 300 Pa
Processing time: 5 to 300 seconds, preferably 100 to 200 seconds
Second reactant supply flow rate: 0.001 to 2 slm, preferably 0.01 to 1 slm
Inert gas supply flow rate (per gas supply pipe): 0 to 20 slm

The second reactant may be, for example, boron trichloride (BCl₃), boron trifluoride (BF₃), boron tribromide (BBr₃), boron triiodide (BI₃), or the like. As the second reactant, one or more of these B- and halogen element-containing substances may be used.

### [Step B2]

In this step, the valve 243d is opened to allow the etching agent to flow into the gas supply pipe 232d. The flow rate of the etching agent is adjusted by the MFC 241d. The etching agent is supplied into the process chamber 201 through the nozzle 249a, and is exhausted from the exhaust port 231a. At this time, the etching agent is supplied to the wafer 200 from the lateral side of the wafer 200, and the wafer 200 is exposed to the etching agent (etching agent supply and exposure). At this time, the valves 243f to 243h may be opened to supply an inert gas into the process chamber 201.

By performing this step under the processing conditions described below, the altered layer formed on the surface of the first film can be caused to react with the etching agent, and at least a part of the altered layer can be converted into a volatile substance and desorbed from the surface of the first film. For example, when an altered layer containing aluminum halide is formed on the surface of the first film, a halogen-containing substance different from the second reactant is supplied as the etching agent to this film, so that the altered layer can be caused to react with the etching agent, and at least a part of the altered layer can be converted into another aluminum halide (e.g., AlClₓF_{y}, or the like), which is a volatile substance, and can be desorbed from the first film. As a result, the surface of the first film is etched with a substantially uniform thickness over the entire area thereof. The etching amount (etching depth) of the first film formed on the first base and the etching amount (etching depth) of the first film formed on the second base are substantially equal to each other.

After the surface of the first film is etched, the valve 243c is closed to stop the supply of the etching agent to the wafer 200. Then, the process chamber 201 is evacuated to remove gaseous substances remaining in the process chamber 201 from the inside of the process chamber 201. Furthermore, the valves 243f to 243h are opened to supply an inert gas into the process chamber 201 to purge the inside of the process chamber 201 (purging).

Processing conditions when supplying the etching agent in step B2 are exemplified as follows.
Processing time: 5 to 200 seconds, preferably 60 to 150 seconds
Etching agent supply flow rate: 0.1 to 10 slm
Inert gas supply flow rate (per gas supply pipe): 0 to 20 slm
   Other processing conditions may be the same as the processing conditions used when supplying the second reactant in step B1.

The etching agent may be, for example, a halogen element-containing substance. The halogen element-containing substance used as the etching agent may be, for example, HF, F₂, Cl₂, NF₃, ClF₃, ClF, or the like. As the etching agent, one or more of these halogen element-containing substances may be used.

### [Performing a Predetermined Number of Times]

Then, a cycle including steps B1 and B2 is performed a predetermined number of times (n_{B} times where n_{B} is an integer of 1 or 2 or more). As a result, as shown in FIG. 4D, it is possible to remove the first film formed on the second base while leaving at least a part of the first film formed on the first base. This is possible because, as described above, in step A, the thickness of the first film formed on the first base is made greater than the thickness of the first film formed on the second base, and in step B, the etching amount (etching depth) of the first film formed on the first base and the etching amount (etching depth) of the first film formed on the second base are made approximately equal to each other. It is preferable that a thickness of the first film on the first base after performing step B is larger than a thickness of the first base. That is, it is preferable that the thickness of the first base is smaller than the thickness of the first film on the first base after performing step B.

### (Step C)

Subsequently, the following steps C1 to C3 are performed.

### [Step C1]

In this step, a modifying agent (second modifying agent) is supplied to the wafer 200 using the same processing procedure and conditions as in step A1 described above (second modifying agent supply and exposure).

By performing this step under the processing conditions described later, as shown in FIG. 4E, it is possible to allow at least a part of the molecular structure of the molecule constituting the second modifying agent to be adsorbed onto the surface of the second base exposed due to the removal of the first film selectively to the surface of the first film remaining on the first base, thereby forming a predetermined adsorption layer (second inhibitor layer). By using the substance exemplified as the first modifying agent in step A1 as the second modifying agent and forming the second inhibitor layer on the surface of the second base, the surface of the second base is modified into a surface terminated with a hydrocarbon group, H, F, and the like, selectively to the surface of the first film remaining on the first base. These terminations (hydrocarbon group terminations, H terminations, F terminations and the like) function as inhibitors that suppress adsorption of the second film-forming agent onto the surface of the second base in step C2 described later. That is, by performing this step, the surface of the second base is modified into a surface having a second termination that suppresses the adsorption of at least a part of the second film-forming agent, selectively to the surface of the first film remaining on the first base.

When both the second base and the first film are made of oxide, the above-mentioned selectivity may be difficult to achieve. Therefore, in order to increase this selectivity, it is preferable to make the density of the material constituting the second base higher than the density of the first film. By increasing the density of the material constituting the second base, the density of the terminations that become the adsorption sites of the second modifying agent (e.g., hydroxyl groups (OH groups), etc.) on the surface of the second base can be made higher than the density of the terminations that become the adsorption sites of the second modifying agent on the surface of the first film. That is, this makes it possible to increase the selectivity of the adsorption of the second modifying agent on the surface of the second base compared to the adsorption of the second modifying agent on the surface of the first film. As a method for making the density of the material constituting the second base higher than the density of the first film, for example, it is desirable to make the processing temperature when forming the second base higher than the processing temperature when forming the first film (i.e., the processing temperature in step A).

After the surface of the second base is selectively modified, the valve 243a is closed to stop the supply of the second modifying agent to the wafer 200. Then, the process chamber 201 is evacuated to remove gaseous substances remaining in the process chamber 201 from the inside of the process chamber 201. Furthermore, the valves 243f to 243h are opened to supply an inert gas into the process chamber 201 to purge the inside of the process chamber 201 (purging).

### [Step C2]

In this step, the valves 243b and 243e are opened to allow a film-forming agent (second film-forming agent) and a catalyst to flow into the gas supply pipes 232b and 232e. The flow rates of the second film-forming agent and the catalyst are adjusted by the MFCs 241b and 241e. The second film-forming agent and the catalyst are supplied into the process chamber 201 through the nozzle 249b and are exhausted from the exhaust port 231a. At this time, the second film-forming agent and the catalyst are supplied to the wafer 200 from the lateral side of the wafer 200, and the wafer 200 is exposed to the second film-forming agent and the catalyst (second film-forming agent+catalyst supply and exposure). At this time, the valves 243f to 243h may be opened to supply an inert gas into the process chamber 201.

By performing this step under the processing conditions described below, at least a part of the molecular structure of the molecule constituting the second film-forming agent can be selectively adsorbed onto the surface of the first film remaining on the first base, and an adsorption layer (second layer) of the second film-forming agent can be selectively formed. As described above, the surface of the second base is modified to a surface having a second termination (a surface having a film-forming inhibition effect) by performing step C1. As a result, the formation of the second layer proceeds on the surface of the first film remaining on the first base selectively to the second base.

After the second layer is selectively formed on the surface of the first film, the valves 243b and 243e are closed to stop the supply of the second film-forming agent and the catalyst to the wafer 200. Then, by the above-mentioned procedure, gaseous substances remaining in the process chamber 201 are removed from the process chamber 201, and the process chamber 201 is purged with the inert gas (purging).

Processing conditions when supplying the second film-forming agent and the catalyst in step C2 are exemplified as follows.
Processing temperature: room temperature (25 degrees C.) to 200 degrees C., preferably room temperature to 150 degrees C.
Processing pressure: 1 to 2000 Pa, preferably 1 to 1333 Pa
Processing time: 1 to 180 seconds, preferably 10 to 120 seconds
Second film-forming agent supply flow rate: 0.001 to 2 slm, preferably 0.01 to 1 slm
Catalyst supply flow rate: 0.001 to 2 slm, preferably 0.01 to 1 slm
Inert gas supply flow rate (per gas supply pipe): 0 to 20 slm

The second film-forming agent may be a substance containing a second predetermined element, particularly a non-metal element (including a metalloid element). The second film-forming agent may be, for example, a Si-containing substance containing silicon (Si) as the second predetermined element. The second film-forming agent may be, for example, a substance containing a halogen element and Si, i.e., halosilane. The halosilane may be, for example, a substance containing Cl and Si, i.e., chlorosilane.

The second film-forming agent may also be, for example, chlorosilane such as monochlorosilane (SiH₃Cl), dichlorosilane (SiH₂Cl₂), trichlorosilane (SiHCl₃), tetrachlorosilane (SiCl₄), hexachlorodisilane (Si₂Cl₆), octachlorotrisilane (Si₃Cl₈), or the like, fluorosilane such as tetrafluorosilane (SiF₄), difluorosilane (SiH₂F₂), or the like, bromosilane such as tetrabromosilane (SiBr₄), dibromosilane (SiH₂Br₂), or the like, and iodosilane such as tetraiodosilane (SiI₄), diiodosilane (SiH₂I₂), or the like.

In addition to the above, the second film-forming agent may be, for example, a substance containing an amino group and Si, i.e., aminosilane. The second film-forming agent may also be, for example, aminosilane such as tetrakis(dimethylamino)silane (Si[N(CH₃)₂]₄), tris(dimethylamino)silane, bis(diethylamino)silane, bis(tertiary butylamino)silane, or (diisopropylamino)silane.

As the second film-forming agent, one or more of these substances may be used.

The catalyst may be, for example, pyridine (C₅H₅N), picoline (C₆H₇N), lutidine (C₇H₉N), triethylamine ((C₂H₅)₃N), or the like. As the catalyst, one or more of these amines may be used.

### [Step C3]

In this step, the valves 243c and 243e are opened to allow a reactant (third reactant) and a catalyst to flow into the gas supply pipes 232c and 232e, respectively. The flow rates of the third reactant and the catalyst are adjusted by the MFCs 241c and 241e. The third reactant and the catalyst are supplied into the process chamber 201 through the nozzles 249c and 249b, and are exhausted from the exhaust port 231a. At this time, the third reactant and the catalyst are supplied to the wafer 200 from the lateral side of the wafer 200, and the wafer 200 is exposed to the third reactant and the catalyst (third reactant+catalyst supply and exposure). At this time, the valves 243f to 243h may be opened to supply an inert gas into the process chamber 201.

By performing this step under the processing conditions described below, the second layer formed on the surface of the first film remaining on the first base can be changed. For example, when an oxidizing agent is used as the third reactant, at least a part of the second layer can be oxidized to form an oxide layer (second oxide layer) containing the constituent elements of the second film-forming agent on the surface of the first film remaining on the first base. In addition, for example, when a nitriding agent is used as the third reactant, at least a part of the second layer can be nitrided to form a nitride layer (second nitride layer) containing the constituent elements of the second film-forming agent on the surface of the first film remaining on the first base.

After the second layer selectively formed on the surface of the first film is changed, the valves 243c and 243e are closed to stop the supply of the third reactant and the catalyst to the wafer 200. Then, by the above-mentioned procedure, gaseous substances remaining in the process chamber 201 are removed from the process chamber 201, and the process chamber 201 is purged with the inert gas.

Process conditions for supplying the third reactant and the catalyst in step C3 are exemplified as follows.
Processing pressure: 1 to 4000 Pa, preferably 1 to 1333 Pa
Third reactant supply flow rate: 0.001 to 2 slm, preferably 0.01 to 1 slm
Catalyst supply flow rate: 0.001 to 2 slm, preferably 0.01 to 1 slm
   Other processing conditions may be the same as those used when supplying the film-forming agent and the catalyst in step C2.

As the third reactant, one or more of the oxidizing agents and the nitriding agents exemplified in step A3 may be used.

As the catalyst, one or more of the catalysts exemplified in step C2 may be used.

### [Performing a Predetermined Number of Times]

Then, a cycle including steps C2 and C3 is performed a predetermined number of times (n_{C} times where n_{C} is an integer of 1 or 2 or more). As a result, as shown in FIG. 4F, a second film can be formed on the first film remaining on the first base. As described above, in step C2, the formation of the second layer proceeds on the surface of the first film remaining on the first base selectively to the second base. Therefore, the formation of the second film by performing the cycle including steps C2 and C3 a predetermined number of times proceeds on the surface of the first film remaining on the first base selectively to the second base.

When a substance containing the above-mentioned non-metal elements, particularly metalloid elements, is used as the second film-forming agent, it is possible to form the second film having a different composition from the first film, i.e., a film containing a non-metal element such as Si.

Furthermore, when a substance containing the above-mentioned non-metal element is used as the second film-forming agent and the above-mentioned oxidizing agent is used as the third reactant, a Si-containing oxide film (a film containing a non-metal element and O), such as a SiO film, a SiON film, a SiOC film, a SiOCN film, a SiBON film, or a SiBCON film, can be formed as the second film.

Furthermore, when a substance containing the above-mentioned non-metal element is used as the second film-forming agent and the above-mentioned nitriding agent is used as the third reactant, a Si-containing nitride film (a film containing a non-metal element and N), such as a SiN film, a SiCN film, or a SiBCN film, can be formed as the second film.

### (After-Purging and Atmospheric Pressure Restoration)

After step C is completed, an inert gas is supplied as a purge gas from each of the nozzles 249a to 249c into the process chamber 201 and is exhausted from the exhaust port 231a. Thus, the inside of the process chamber 201 is purged, and the gas and reaction by-products remaining in the process chamber 201 are removed from the inside of the process chamber 201 (after-purging). Thereafter, the atmosphere in the process chamber 201 is replaced with an inert gas (inert gas replacement), and the pressure in the process chamber 201 is returned to the atmospheric pressure (atmospheric pressure restoration).

### (Boat Unloading and Wafer Discharging)

Thereafter, the seal cap 219 is lowered by the boat elevator 115, and the lower end of the manifold 209 is opened. Then, the processed wafers 200 are unloaded from the lower end of the manifold 209 to the outside of the reaction tube 203 while being supported by the boat 217 (boat unloading). After the boat unloading, the shutter 219s is moved, and the lower end opening of the manifold 209 is sealed by the shutter 219s via the O-ring 220c (shutter closing). After being unloaded to the outside of the reaction tube 203, the processed wafers 200 are taken out of the boat 217 (wafer discharging).

It is preferable that steps A to C are performed in the same process chamber, or in multiple process chambers connected via a transfer chamber under a vacuum or a non-oxidizing atmosphere (i.e., in-situ). If a series of processes is performed in-situ, the wafer 200 is not exposed to the ambient air during the process, so that the wafer 200 can be processed consistently while being placed under a vacuum or a non-oxidizing atmosphere, and the process can be performed without causing natural oxidation of the surface.

### (3) Effects of the Present Embodiment

According to the present embodiment, one or more of the following effects may be obtained.
(a) By performing the above-mentioned steps A and B, it becomes possible to precisely form a film in the recess provided on the surface of a substrate. That is, in the recess having a bottom surface formed by a first base and a side surface formed by a second base, a first film can be formed on the first base selectively to the second base.
(b) In step B, by performing the cycle including steps B1 and B2 a predetermined number of times, it becomes possible to selectively remove the first film from the second base with good controllability while leaving at least a part of the first film formed on the first base. That is, it becomes possible to selectively form the first film on the first base with greater precision.
(c) In step A, by performing step A1 of selectively modifying the surface of the second base into a surface having a first termination before supplying the first film-forming agent to the substrate, it becomes easy to form the first film on the first base with a thickness greater than that of the first film formed on the second base. As a result, it becomes possible to selectively form the first film on the first base with greater precision.
(d) In step A, by performing the cycle including steps A2 and A3 a predetermined number of times after performing step A1, it is possible to precisely control the thickness of the first film formed in the recess. As a result, the selective formation of the first film on the first base can be performed more precisely.
(e) Since the first film is a film containing a metal element, it becomes possible to precisely perform the film-forming process in step A and the etching process in step B. As a result, it becomes possible to selectively form the first film on the first base with greater precision.

The same effects can be obtained by forming the first film as a film containing a metal element and O. In addition, the first film can be used as an oxide high-k film with a large dielectric constant.

The same effects can be obtained by forming the first film as a film containing a metal element and N. Furthermore, the first film can be used as a nitride high-k film with a large dielectric constant. In addition, since the first film does not contain oxygen, it is possible to avoid oxidation of the first base when performing step A.
(f) By performing step C after performing step B, it becomes possible to form a second film having a composition different from that of the first film on the first film remaining on the first base.
(g) In step C, by performing step C1 of modifying the surface of the second base into a surface having a second termination before supplying the second film-forming agent to the substrate, it becomes possible to more precisely selectively form the second film on the first film remaining on the first base.
(h) In step C, by performing the cycle including steps C2 and C3 a predetermined number of times after performing step C1, it is possible to precisely control the thickness of the second film formed in the recess. As a result, the selective formation of the second film on the first film can be performed more precisely.
(i) By forming a film containing a metal element and O as the first film in step A and forming a film containing a non-metal element and O as the second film in step C, it is possible to selectively form a stacked structure of these films on the first base.

The same effects can be obtained by forming a film containing a metal element and N as the first film in step A and forming a film containing a non-metal element and O as the second film in step C. Furthermore, since the first film to be formed does not contain oxygen in step A, it is possible to avoid oxidation of the first base.

The same effects can be obtained by forming a film containing a metal element and N as the first film in step A and forming a film containing a non-metal element and N as the second film in step C. Furthermore, since the first film does not contain oxygen in step A, it is possible to avoid oxidation of the first base, and since the second film to be formed does not contain oxygen in step C, it is possible to avoid oxidation of the first film and the first base.
(j) When the second base is a film containing O, by performing step A1, it becomes easy to modify the surface of the second base into a surface having a first termination formed thereon. This makes it possible to selectively form the first film on the first base with greater precision.

Furthermore, when the second base is a film containing O, by performing step C1, it becomes easy to modify the surface of the second base into a surface having a second termination formed thereon. As a result, it becomes possible to more precisely selectively form the second film on the first film remaining on the first base.
(k) If the first film is used, for example, as a film constituting a charge trap layer of a memory cell, it is possible to improve the performance of a flash memory device.
(l) By making a thickness of the first base smaller than the thickness of the first film on the first base after performing step B, when the first film is used as a film constituting a charge trap layer of a memory cell, it is possible to reduce interference between adjacent charge trap layers and improve the performance of a flash memory device.
(m) The above-mentioned effects can be obtained in the same way even when a specific substance is arbitrarily selected from the various modifying agents, various film-forming agents, various reactants, various etching agents, and various inert gases described above.

### (4) Modifications

This embodiment may be modified as follows. The modifications shown below may be combined in any combination.

### (Modification 1)

After performing step C, step D of supplying an oxidizing agent to the substrate as a reactant (fourth reactant) may be performed using the same processing procedure as that used in step A3.

Processing conditions when supplying the oxidizing agent in step D are exemplified as follows.
Processing temperature: 350 to 1000 degrees C., preferably 400 to 650 degrees C.
Processing pressure: 1 to 105000 Pa, preferably 10 to 10000 Pa
Processing time: 1 to 10000 seconds, preferably 5 to 3600 seconds
Oxidizing agent supply flow rate: 0.01 to 10 slm, preferably 0.1 to 5 slm
Inert gas supply flow rate (per gas supply pipe): 0 to 20 slm

The oxidizing agent may be, for example, an oxygen-containing substance having strong oxidizing power, such as ozone (O₃), oxygen (O₂)+hydrogen (H₂), O₂+deuterium (D₂), O₃+H₂, O₃+D₂, water vapor (H₂O), hydrogen peroxide (H₂O₂), or O₂ or O₃ excited into a plasma state. As the oxidizing agent, one or more of these substances may be used. In this regard, the description of two substances together, such as “O₂+H₂”, means a mixture of O₂ and H₂.

When supplying a mixture, two substances may be mixed (premixed) in a supply pipe and then supplied into the process chamber 201, or two substances may be supplied into the process chamber 201 separately from different supply pipes and mixed (post-mixed) in the process chamber 201.

In this modification as well, the same effects as those of the above-described embodiment can be obtained.

Furthermore, when a metal nitride film is formed as the first film in step A, in this modification, by performing step D, it becomes possible to modify (change) at least a part of the first film into an oxide film such as a metal oxide film or a metal oxynitride film via the second film.

Furthermore, when a metal oxide film is formed as the first film in step A, in this modification, by performing step D, it becomes possible to modify (change) at least a part of the first film into a denser oxide film with fewer impurities via the second film.

Furthermore, in this modification, by modifying (oxidizing) the first film via the second film, it becomes possible to modify (change) at least a part of the second film into a denser oxide film with fewer impurities.

### (Modification 2)

In step C, an oxidizing agent having strong oxidizing power, such as O₃, O₂+H₂, O₂+D₂, O₃+H₂, O₃+D₂, H₂O₂, or O₂ or O₃ excited into a plasma state, may be used as the reactant (third reactant). The processing conditions may be the same as those used when supplying the oxidizing agent in step D of modification 1.

In this modification as well, the same effects as those of the above-described embodiment can be obtained.

Furthermore, when a metal nitride film is formed as the first film in step A, in this modification, by performing step C using an oxidizing agent having strong oxidizing power, it becomes possible to modify (change) at least a part of the first film, which is the base of the second film, into an oxide film such as a metal oxide film or a metal oxynitride film when forming the second film.

Furthermore, when a metal oxide film is formed as the first film in step A, in this modification, by performing step C using an oxidizing agent having strong oxidizing power, it becomes possible to modify (change) at least a part of the first film into a denser oxide film with fewer impurities.

In addition, in this modification, by performing step C using an oxidizing agent having strong oxidizing power as the third reactant, it becomes possible to change the second film into a denser oxide film with few impurities.

### (Modification 3)

After performing step B and before performing step C, step E of supplying an oxidizing agent containing O and H, such as H₂O or H₂O₂, to the substrate as a reactant (fifth reactant) may be performed by the same processing procedure and processing conditions as those of step A3.

In this modification as well, the same effects as those of the above-described embodiment can be obtained.

In this modification, by performing step E of supplying the oxidizing agent containing 0 and H to the substrate after performing step B and before performing step C, it is possible to remove halogen elements (Cl, F, etc.) adsorbed to and remained on the surface of the second base by performing step B, and to terminate the surface of the second base with OH groups. This makes it possible to efficiently perform selective termination of the second base in step C1.

### (Modification 4)

In step B, the first film may be etched using an etching agent alone without using the second reactant.

In this case, the etching agent may be supplied intermittently a number of times, or may be supplied continuously.

In this modification as well, the same effects as those of the above-described embodiment can be obtained.

### Other Embodiments of the Present Disclosure

The embodiment of the present disclosure has been specifically described above. However, the present disclosure is not limited to the above-described embodiment, and various modifications may be made without departing from the spirit of the present disclosure.

In the above-mentioned embodiment, there has been described the example in which the metal oxide film or the metal nitride film is formed using the substance containing a metal element as the first film-forming agent in step A. The present disclosure is not limited to the above-described embodiment, and may be applied, for example, to a case where a substance containing a non-metal element, particularly the above-mentioned metalloid element, is used as the first film-forming agent in step A to form an oxide film or a nitride film containing the element. In addition, in the above-mentioned embodiment, there has been described the example in which the oxide film or the nitride film containing a non-metal element is formed using the substance containing a non-metal element as the second film-forming agent in step C. The present disclosure is not limited to the above-described embodiment, and may be applied, for example, to a case where a substance containing the above-mentioned metal element is used as the second film-forming agent in step C to form an oxide film or a nitride film containing the metal element.

It is preferable that the recipe used for each process is prepared separately according to the processing contents and are recorded and stored in the memory device 121c via an electric communication line or an external memory device 123. When starting each process, it is preferable that the CPU 121a properly selects an appropriate recipe from a plurality of recipes recorded and stored in the memory device 121c according to the process contents. This makes it possible to form films of various film types, composition ratios, film qualities and film thicknesses with high reproducibility in the processing apparatus. In addition, the burden on an operator can be reduced, and each process can be quickly started while avoiding operation errors.

The above-described recipes are not limited to the newly prepared ones, but may be prepared by, for example, changing the existing recipes already installed in the processing apparatus. In the case of changing the recipes, the recipes after the change may be installed in the processing apparatus via an electric communication line or a recording medium in which the recipes are recorded. In addition, the input/output device 122 provided in the existing processing apparatus may be operated to directly change the existing recipes already installed in the processing apparatus.

In the above-described embodiment, there has been described the example in which a film is formed by using a batch type processing apparatus for processing a plurality of substrates at a time. The present disclosure is not limited to the above-described embodiment, but may be applied to, for example, a case where a film is formed using a single-substrate type processing apparatus for processing one or several substrates at a time. Furthermore, in the above-described embodiment, there has been described the example in which a film is formed using a processing apparatus having a hot wall type process furnace. The present disclosure is not limited to the above-described embodiment, but may also be applied to a case where a film is formed using a processing apparatus having a cold wall type process furnace.

In the above-described embodiment, there has been described the case where a series of processing sequences of steps A to C are performed in situ. The present disclosure is not limited to the above-described embodiment. For example, any one of steps A to C and any other step may be performed in different process chambers of different processing apparatuses (ex-situ), or may be performed in different process chambers of the same processing apparatus.

Even when these processing apparatuses are used, each process may be performed under the same processing procedures and processing conditions as those of the above-described embodiment and modifications. The same effects as those of the above-described embodiment and modifications may be obtained.

The above-described embodiment and modifications may be used in combination as appropriate. The processing procedure and processing conditions at this time may be, for example, the same as the processing procedures and processing conditions of the above-described embodiment and modifications.

According to the present disclosure in some embodiments, it is possible to precisely form a film within a recess on a surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a film-forming agent to the substrate having a recess on a surface thereof, the recess having a bottom surface formed by a first base and a side surface formed by a second base, and forming a first film on the first base with a thickness greater than a thickness of a first film formed on the second base; and
(b) supplying an etching agent to the substrate, and removing the first film formed on the second base while leaving at least a part of the first film formed on the first base.

2. The method of claim 1, wherein in (b), a cycle including (b1) supplying the etching agent to the substrate and (b2) supplying a second reactant that differs from the etching agent and reacts with the first film to the substrate is performed a predetermined number of times.

3. The method of claim 1, wherein in (a), before supplying the film-forming agent to the substrate, (a1) supplying a modifying agent to the substrate to modify the surface of the second base selectively to the surface of the first base into a surface having a first termination that suppresses adsorption of at least a part of the film-forming agent is performed.

4. The method of claim 3, wherein in (a), after performing (a1), a cycle including (a2) supplying the film-forming agent to the substrate and (a3) supplying a first reactant to the substrate is performed a predetermined number of times.

5. The method of claim 1, wherein in (a), a film containing a metal element is formed as the first film.

6. The method of claim 1, wherein in (a), a film containing a metal element and oxygen is formed as the first film.

7. The method of claim 1, wherein in (a), a film containing a metal element and nitrogen is formed as the first film.

8. The method of claim 1, further comprising:
(c) after performing (b), supplying a second film-forming agent to the substrate to form a second film having a different composition from the first film on the first film.

9. The method of claim 8, wherein in (c), before supplying the second film-forming agent to the substrate, (c1) supplying a second modifying agent to the substrate to modify the surface of the second base selectively to the surface of the first film into a surface having a second termination that suppresses adsorption of at least a part of the second film-forming agent is performed.

10. The method of claim 9, wherein in (c), after performing (c1), a cycle including (c2) supplying the second film-forming agent to the substrate and (c3) supplying a third reactant to the substrate is performed a predetermined number of times.

11. The method of claim 8, wherein in (a), a film containing a metal element and oxygen is formed as the first film, and in (c), a film containing a non-metal element and oxygen is formed as the second film.

12. The method of claim 8, wherein in (a), a film containing a metal element and nitrogen is formed as the first film, and in (c), a film containing a non-metal element and oxygen is formed as the second film.

13. The method of claim 8, wherein in (a), a film containing a metal element and nitrogen is formed as the first film, and in (c), a film containing a non-metal element and nitrogen is formed as the second film.

14. The method of claim 12, wherein the second base is a film containing oxygen.

15. The method of claim 12, further comprising:
(d) after performing (c), supplying an oxidizing agent to the substrate to modify at least a part of the first film into an oxide film via the second film.

16. The method of claim 1, wherein the first film is a film that constitutes at least a part of a charge trap layer of a memory cell.

17. The method of claim 1, wherein a thickness of the first base is smaller than the thickness of the first film on the first base after (b) is performed.

18. A method of manufacturing a semiconductor device, comprising the method of claim 1.

19. A non-transitory computer-readable recording medium storing a program that causes, by a computer, a substrate processing apparatus to perform a process comprising:
(a) supplying a film-forming agent to a substrate having a recess on a surface thereof, the recess having a bottom surface formed by a first base and a side surface formed by a second base, and forming a first film on the first base with a thickness greater than a thickness of a first film formed on the second base; and
(b) supplying an etching agent to the substrate, and removing the first film formed on the second base while leaving at least a part of the first film formed on the first base.

20. A substrate processing apparatus, comprising:
a film-forming agent supply system configured to supply a film-forming agent to a substrate;
an etching agent supply system configured to supply an etching agent to the substrate; and
a controller configured to control the film-forming agent supply system and the etching agent supply system so as to perform (a) supplying the film-forming agent to the substrate having a recess on a surface thereof, the recess having a bottom surface formed by a first base and a side surface formed by a second base, and forming a first film on the first base with a thickness greater than a thickness of a first film formed on the second base, and (b) supplying the etching agent to the substrate, and removing the first film formed on the second base while leaving at least a part of the first film formed on the first base.
